(19) United States
(12) Patent Application Publication
(10) Pub. No.: US 2021/0345519 A1
(43) Pub. Date: Nov. 4, 2021

(54) TECHNOLOGIES FOR RECONFIGURABLE HEAT SINKS

(71) Applicant: Intel Corporation, Santa Clara, CA (US)

(72) Inventors: Wenbin Tian, Shanghai (CN); Yingqiong Bu, Shanghai (CN); Yanbing Sun, Shanghai (CN); Yang Yao, Shanghai (CN); Yuehong Fan, Shanghai (CN); Ming Zhang, Shanghai (CN); Casey Robert Winkel, Hillsboro, OR (US); Jin Yang, North Plains, OR (US); David Shia, Portland, OR (US); Mohanraj Prabhugoud, Beaverton, OR (US)

(73) Assignee: Intel Corporation, Santa Clara, CA (US)

(21) Appl. No.: 17/359,405

(22) Filed: Jun. 25, 2021

Related U.S. Application Data
(60) Provisional application No. 63/045,774, filed on Jun. 29, 2020.

(51) Int. Cl. H05K 7/20; H01L 23/367; H01L 23/427; H01L 23/40

(52) U.S. Cl. CPC H05K 7/2039; H01L 23/3672; H05K 7/20336; H01L 23/40; H01L 23/427

(57) ABSTRACT

Techniques for reconfigurable heat sinks are disclosed. In one embodiment, a compute system includes a heat sink includes a core fin assembly with two removable lateral fin assemblies. The lateral fin assemblies may be above one or more components of the compute system, such as one or more memory modules. With the lateral fin assemblies in place, the cooling capacity of the heat sink is increased, but the more memory modules may be difficult or impossible to service. With the lateral fin assemblies removed, the memory modules can be serviced (e.g., replaced). In another embodiment, a lateral fin assembly of a heat sink is attached to a heat pipe. The lateral fin assembly can rotate relative to the heat pipe, allowing the lateral fin assembly to fit within a 2U form factor in one configuration and allow access to components under the lateral fin assembly in another configuration.

### CROSS-REFERENCE TO RELATED APPLICATIONS

This applications claims the benefit of provisional patent application No. 63/045,774 filed on Jun. 29, 2020 and entitled “DETACHABLE ENHANCED VOLUME AIR COOLED HEAT SINK,” by Wenbin Tian et al.,” filed Jun. 29, 2020. The entirety of that application is incorporated herein by reference.

### BACKGROUND

Modern integrated circuit components such as processor units can generate large amounts of heat and may require relatively large heat sinks to dissipate energy. For air-cooled heat sinks, a larger volume for heat transfer components such as fins allows for a greater cooling capacity. In practice, making heat sinks larger causes problems. Making heat sinks taller may require a larger vertical footprint for a server. Making heat sinks longer or wider may require a larger “keep out” zone in which certain other components cannot be placed.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is a parallel projection of a simplified diagram of at least one embodiment of a system with a reconfigurable heat sink in a first configuration.

FIG. 2 is a parallel projection of the system of FIG. 1 with the heat sink in a second configuration.

FIG. 3 is a parallel projection of a simplified diagram of at least one embodiment of a system with a reconfigurable heat sink in a first configuration.

FIG. 4 is a parallel projection of the system of FIG. 3 with the heat sink in a second configuration.

FIG. 5 is a parallel projection of the heat sink of FIG. 3 at least partially disassembled.

FIG. 6 is a parallel projection of a simplified diagram of at least one embodiment of a system with a reconfigurable heat sink in a first configuration.

FIG. 7 is a parallel projection of the system of FIG. 6 with the heat sink in a second configuration.

FIG. 8 is one embodiment of a simplified flowchart for a method of using a reconfigurable heat sink.

FIG. 9 is a block diagram of an exemplary computing system in which technologies described herein may be implemented.

### DETAILED DESCRIPTION OF THE DRAWINGS

In order to increase the cooling capacity of a heat sink, in one embodiment, one or more fin assemblies positioned laterally to a core fin assembly can be used. In order to mitigate or prevent any difficulty in accessing components under the lateral fin assemblies, the lateral fin assemblies can be repositioned, allowing access to components underneath. Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. The term “coupled,” “connected,” and “associated” may indicate elements electrically, electromagnetically, thermally, and/or physically (e.g., mechanically or chemically) co-operate or interact with each other and do not exclude the presence of intermediate elements between the coupled, connected, or associated items absent specific contrary language. Terms modified by the word “substantially” include arrangements, orientations, spacings, or positions that vary slightly from the meaning of the unmodified term. For example, surfaces described as being substantially parallel to each other may be off of being parallel with each other by a few degrees.

The description may use the phrases “in an embodiment,” “in embodiments,” “in some embodiments,” and/or “in various embodiments,” each of which may refer to one or more of the same or different embodiments. Furthermore, the terms “comprising,” “including,” “having,” and the like, as used with respect to embodiments of the present disclosure, are synonymous.

Reference is now made to the drawings, wherein similar or same numbers may be used to designate the same or similar parts in different figures. The use of similar or same numbers in different figures does not mean all figures including similar or same numbers constitute a single or same embodiment. In the following description, for purposes of explanation, numerous specific details are set forth in order to provide a thorough understanding thereof. It may be evident, however, that the novel embodiments can be practiced without these specific details. In other instances, well-known structures and devices are shown in block diagram form to facilitate a description thereof. The intention is to cover all modifications, equivalents, and alternatives within the scope of the claims.

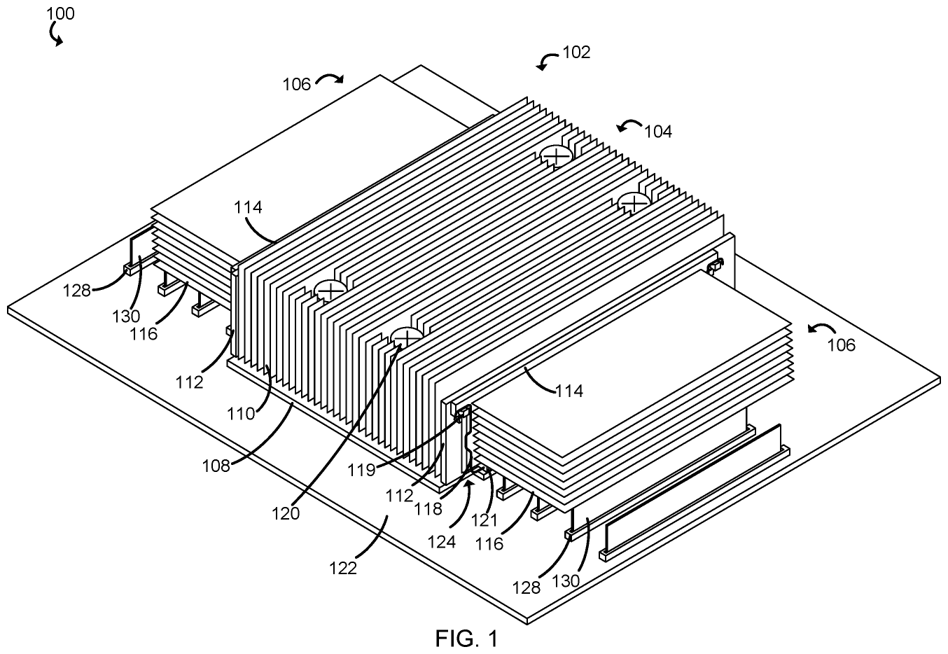

Referring now to FIG. 1, in one embodiment, an illustrative system 100 shown in FIG. 1 includes a heat sink 102, which has a core fin assembly 104 and two lateral fin assemblies 106. The heat sink 102 includes a base 108, to which several fins 110 are mechanically and thermally coupled. A thermally conductive metal block 112 is positioned at each of two ends of the core fin assembly 104. A thermally conductive metal block 114 of the lateral fin assemblies 106 is mated with the metal block 112, establishing strong thermal contact between the mated blocks 112, 114. The lateral fin assemblies 106 include several fins 116 mechanically and thermally coupled to the metal block 114. In the illustrative embodiment, one or more spring clips 118 attached to the core fin assembly 104 are connected to a protrusion 119 extending from the metal block 114, applying a downward force to the lateral fin assembly 106. In the illustrative embodiment, the edge of the metal block 114 has a wedged shape and mates with a lip 121 extending from the metal block 112. As such, the wedged-shape edge of the metal block 114 redirects the downward force to a force that is towards the metal block 112, establishing strong thermal coupling between the metal block 112 and the metal block 114. In the illustrative embodiment, the lateral fin assemblies 106 extend over memory module slots 128, in which memory modules 130 are inserted.

The heat sink 102 is fastened to the system board 122, such as by using spring screws 120. The heat sink 102 is positioned on top of an integrated circuit component 124 (not visible in FIG. 1), such as a processor unit. In the illustrative embodiment, a thermal interface material (TIM) layer is between the heat sink 102 and the integrated circuit component 124 to facilitate thermal coupling between the components. A TIM layer can be any suitable material, such as a silver thermal compound, thermal grease, phase change materials, indium foils, or graphite sheets.

As used herein, the term “integrated circuit component” refers to a packaged or unpacked integrated circuit product. A packaged integrated circuit component comprises one or more integrated circuits. In one example, a packaged integrated circuit component contains one or more processor units and a land grid array (LGA) or pin grid array (PGA) on an exterior surface of the package. In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any type of computing system component or type of component described or referenced herein, such as a processor unit (e.g., system-on-a-chip (SoC), processor cores, graphics processor unit (GPU), accelerator), I/O controller, chipset processor, memory, network interface controller, or a three-dimensional integrated circuit (3D IC) face-to-face-based packaging chip such as an Intel® Foveros chip. In one embodiment, the integrated circuit component 124 is a processor unit, such as a single-core processor, a multi-core processor, a desktop processor, a server processor, a data processing unit, a central processing unit, a graphics processing unit, etc. The processor unit may include an integrated memory, such as a high-bandwidth memory. The integrated circuit component 124 may include one or more chips integrated into a multi-chip package (MCP).

The various dies of the integrated circuit component 124 may generate any suitable amount of heat. For example, in one embodiment, the integrated circuit component 124 may generate up to 500 Watts of power. Any particular die of the integrated circuit component may generate, e.g., 1-500 Watts and may be maintained at less than any suitable temperature, such as 50-150° C. The integrated circuit component 124 may have any suitable power density in different areas, such as 0-500 Watts/cm². The lateral fin assemblies 106 may increase the cooling power of the heat sink 102. For example, in one embodiment, the lateral fin assemblies 106 may increase the cooling capacity of the heat sink 102 from 300 Watts to 350 Watts. More generally, the lateral fin assemblies 106 (and other lateral fin assemblies disclosed herein) may provide any suitable amount of additional cooling capacity, such as 1-200 Watts.

The illustrative core fin assembly 104 has a heat sink base 108 and several heat sink fins 110. The fins 110 may be any structure configured to transfer heat to air flowing over the fins 110. A fin 110 may be thermally coupled to the base 108, a heat pipe, a three-dimensional vapor chamber, and/or the like. A fin may be elongated in two dimensions (that is, have a planar shape), may be elongated in one direction (i.e., have a column-like shape), and/or any other suitable shape. In the illustrative embodiment, the fins 110 are thin, flat structures extending out of a metal block such as the base 108. The fins 110 may be any suitable shape, such as a plane, a rod, a folded sheet, etc. In the illustrative embodiment, the heat sink fins 110 are bonded to the heat sink base 108 by solder, glue, or other adhesive. In other embodiments, the heat sink fins 110 may be removably fastened to the heat sink base 108. In some embodiments, the core fin assembly 104 may be a unitary piece that includes both the heat sink base 108 and the heat sink fins 110. More generally, the core fin assembly 104 may be manufactured in any suitable manner, such as extrusion, skiving, stamping, forging, machining, 3D printing, etc.

One purpose of the core fin assembly 104 is to absorb heat from the integrated circuit component 124 and transfer the heat to air. In some embodiments, a fan (not shown in FIG. 1) may blow air onto and/or through the heat sink fins 110.

The core fin assembly 104 may be made from any suitable material. In the illustrative embodiment, the heat sink base 108, the heat sink fins 110, and the metal block 112 are made from a high-thermal-conductivity material, such as copper, aluminum, or another material with a thermal conductivity greater than 100 W/(m×K). In some embodiments, the heat sink base 108 and the heat sink fins 110 may be made of a different material. For example, the heat sink base 108 may be aluminum, and the heat sink fins 110 may be copper. In some embodiments, the heat sink base 108 may have more than one layer of different materials.

The core fin assembly 104 may have any suitable shape or dimensions. For example, the core fin assembly 104 may have a width of 10-250 millimeters, a length of 10-250 millimeters, and/or a height of 10-100 millimeters. In the illustrative embodiment, the core fin assembly 104 has a width of about 75 millimeters, a length of about 150 millimeters, and a height of about 30 millimeters. The thickness of the base 108 may be any suitable thickness, such as 1-10 millimeters. In the illustrative embodiment, the base 108 has a thickness of about 5 millimeters. The height of the fins 110 may be any suitable height, such as 5-100 millimeters. In the illustrative embodiment, the system 100 is designed to fit in a 2U form factor. In other embodiments, the system 100 may be designed to fit in any suitable form factor, such as a 1U, 3U, 4U, desktop form factor, etc. The metal block 112 may have any suitable length, height, or thickness. For example, the metal block 112 may have a length or width of 10-250 millimeters and/or a thickness of 1-10 millimeters. In the illustrative embodiment, the metal block 112 has a flat surface that mates with a flat surface of the metal block 114. In other embodiments, the metal block 112 and/or metal block 114 may have a surface with a different shape, such as a shape that is curved, has one or more steps, one or more pedestals, etc.

The illustrative core fin assembly 104 is a rectangular shape. In other embodiments, the core fin assembly 104 may be any suitable shape, such as a square, a circle, etc. The illustrative heat sink base 108 has a flat surface on the bottom. In some embodiments, one or more heat pipes or vapor chambers may be present in the core fin assembly 104 (such as embedded in or in contact with the heat sink base 108) to transfer heat from a central region of the heat sink base 108 to the edges of the heat sink base 108 and/or to the metal block 112. In some embodiments, the heat sink 102 may include other heat-transferring components such as a thermoelectric heater/cooler, etc.

The lateral fin assemblies 106 is, in the illustrative embodiment, constructed similarly to the core fin assemblies 104. For example, the metal block 114 and heat sink fins 116 may be similar to the heat sink base 108 and heat sink fins 110, respectively, a description of which will not be repeated in the interest of clarity. In the illustrative embodiment, there is a TIM layer between the metal block 112 and the metal block 114.

The illustrative heat sink 102 is fastened to the system board 122 by fasteners 120. In the illustrative embodiment, fasteners 120 are embodied as screws or bolts. Fasteners 120 may have a spring that applies a downward force on the heat sink base 108 towards the integrated circuit component 124. The fasteners 120 can screw directly into threaded holes of the system board 122 or may be secured by, e.g., a nut. Additionally or alternatively, the fasteners 120 may be embodied as any other suitable type of fastener, such as a torsion fastener, a spring screw, one or more clips, a land grid array (LGA) loading mechanism, and/or a combination of any suitable types of fasteners. In the illustrative embodiment, the fasteners 120 are removable. In other embodiments, some or all of the fasteners 120 may permanently secure the heat sink 102 to the system board 122. In some embodiments, the system board 122 may include a bolster plate and/or a backplate, and the fasteners 120 may fasten to the bolster plate and/or backplate.

In the illustrative embodiment, the system board 122 may be embodied as a mainboard of a compute device card such as a graphics card. The system board 122 may include other components not shown, such as interconnects, other electrical components such as capacitors or resistors, additional sockets for components such as memory or peripheral cards, connectors for peripherals, etc. In other embodiments, the system board 122 may form or be a part of another component of a computer system, such as a mezzanine board, a peripheral board, etc. The system board 122 may be embodied as a peripheral card compatible with a peripheral component interconnect express (PCIe) standard. The illustrative system board 122 is a fiberglass board made of glass fibers and a resin, such as FR-4. In other embodiments, other types of circuit boards may be used.

The memory modules 130 may be any suitable type of memory modules, such as dynamic random-access memory (DRAM), static random-access memory (SRAM), and/or non-volatile memory (e.g., flash memory, chalcogenide-based phase-change non-volatile memories).

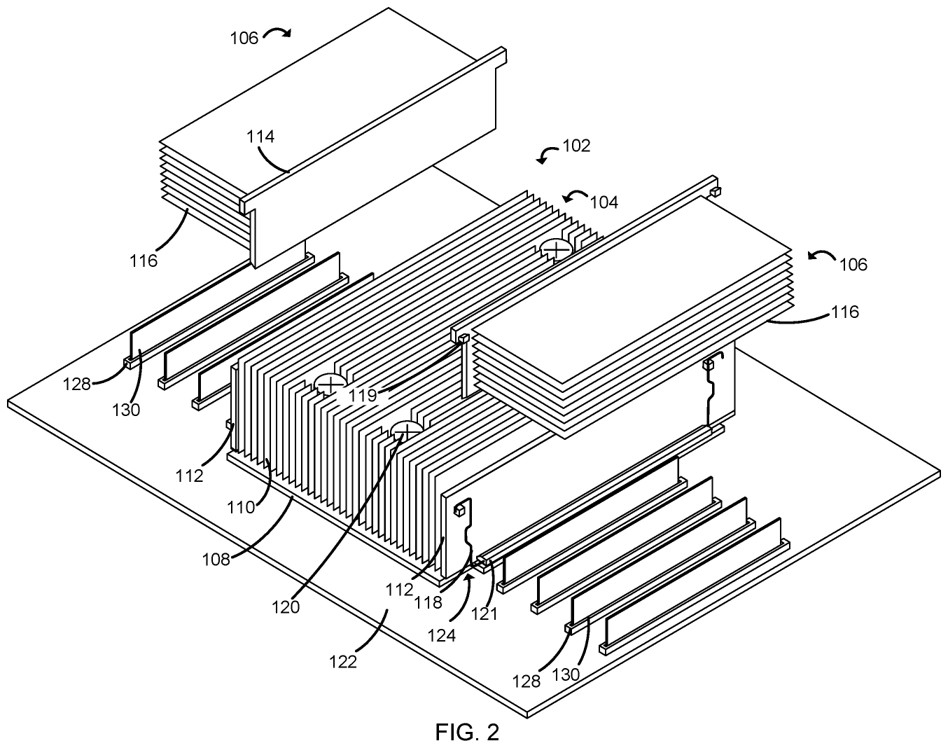

In use, the lateral fin assemblies 106 are positioned as shown in FIG. 1, thermally coupled to the core fin assembly 104 and the integrated circuit component 124. However, when positioned as shown in FIG. 1, the lateral fin assemblies 106 would make it difficult or impossible to remove the memory modules 130 for repair or replacement. In order to provide easier access to the memory modules 130, the heat sink 102 can be reconfigured by removing one or both of the lateral fin assemblies 106, as shown in FIG. 2. In order to remove the lateral fin assemblies 106, in one embodiment, the spring clips 118 can be removed from the protrusion 119, and then the lateral fin assemblies 106 can be removed. With the lateral fin assemblies 106 removed, the memory modules 130 or other components under the lateral fin assembly 106 can be serviced. It should be appreciated that, in the illustrative embodiment, the core heat fin assembly 104 remains mated with the integrated circuit component 124 when the lateral fin assemblies 106 are removed.

After the memory modules 130 or other components are serviced, the lateral fin assemblies 106 can be reattached. In the illustrative embodiment, any previous TIM layer is removed from the metal blocks 112, 114, and a new TIM layer is applied before reattaching the lateral fin assemblies 106.

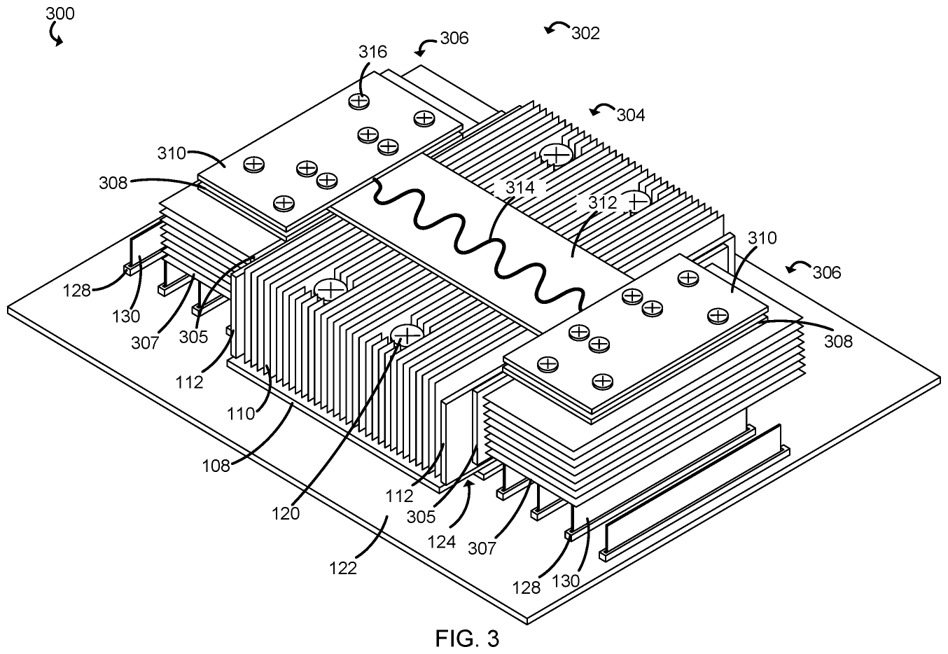

Referring now to FIG. 3, in one embodiment, a system 300 includes a heat sink 302. The heat sink 302 has a core fin assembly 304 and two lateral fin assemblies 306. The lateral fin assemblies 306 are connected to each other by a spring 314. The spring 314 applies a force to each lateral fin assembly 306 in the direction of the other lateral fin assembly 106, which is transferred to a metal block 305 of the lateral fin assembly 306. The metal block 305 is pressed against a metal block 112 of the heat sink 102, establishing strong thermal coupling between the metal blocks 112, 305.

The system 300 includes several components similar or identical to those described above in regard to the system 100. For example, the heat sink 302 includes a base 108, fins 110, a metal block 112, and one or more fasteners 120, which may be similar to the corresponding component of the heat sink 102. The system 300 includes a system board 122, an integrated circuit component 124, one or more memory module slots 128, one or more memory modules 130, etc. The description of each corresponding component of the system 300 will not be repeated in the interest of clarity.

The lateral fin assemblies 106 include several fins 307 mechanically and thermally coupled to the metal block 305. The lateral fin assemblies 106 include a mounting plate 308 that is fixed relative to the metal block 305. For example, the mounting plate 308 may be glued, soldered, welded, screwed, or otherwise mated with the metal block 305. A spring plate 310 of each lateral fin assembly 306 is connected to the spring plate 310 of the other lateral fin assembly 306 by the spring 314. The mounting plate 308 and/or spring plate 310 may be any suitable material, such as copper, aluminum, steel, plastic, etc. The spring 314 may be any suitable spring, such as a wire, a strip of metal, etc. In some embodiments, the spring 314 may be created together with the spring plate 310 from a single metal plate.

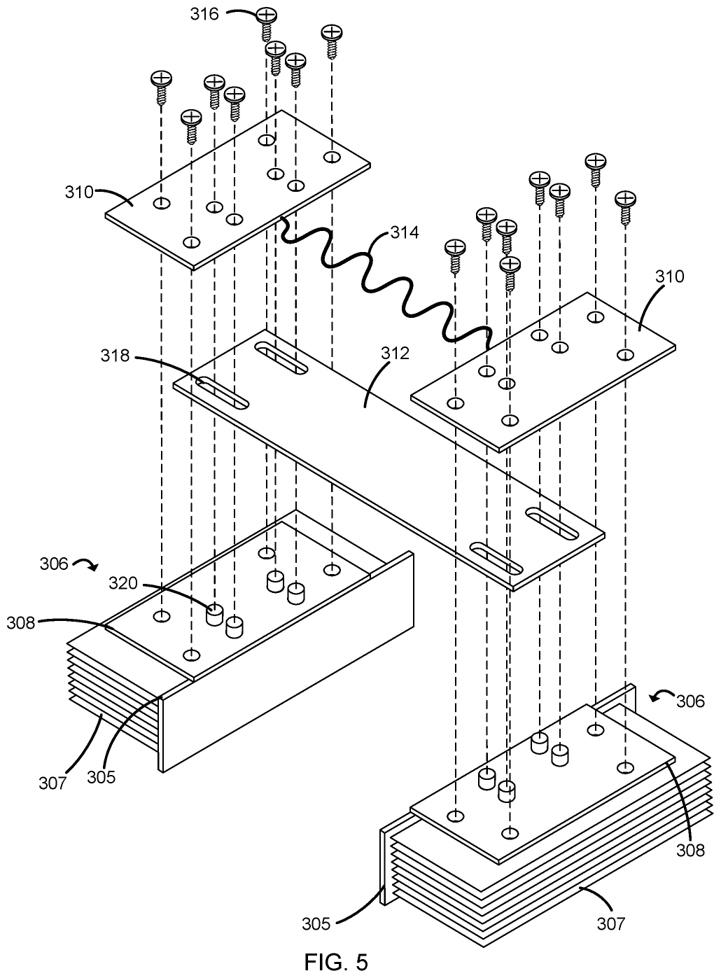

The heat sink 302 includes an alignment plate 312. The alignment plate 312 keeps the lateral fin assemblies 106 oriented in the same orientation relative to each other and prevents movement of one lateral fin assembly 106 relative to the other lateral fin assembly 106 in every direction except the direction in which the spring 314 applies a force. In the illustrative embodiment, one or more pedestals 320 extend from a surface of the mounting plate 308, as shown in FIG. 5. One or more screws 316 passes through the spring plate 310, through a slot 318 in the alignment plate 312, and mate with the pedestals 320 of the mounting plate 308. The pedestals 320 and screws 316 can slide along the slot 318, allowing the lateral fin assemblies 306 to move relative to each other along the axis of the spring 314.

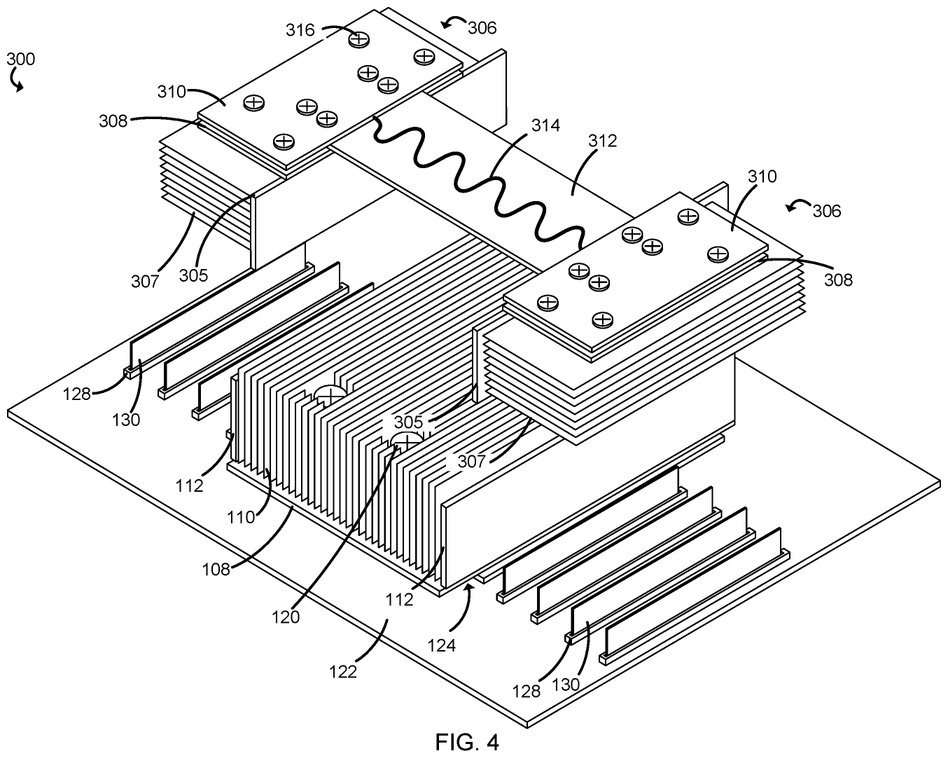

In use, the lateral fin assemblies 306 are positioned as shown in FIG. 3, thermally coupled to the core fin assembly 304 and the integrated circuit component 124. However, when positioned as shown in FIG. 3, the lateral fin assemblies 306 would make it difficult or impossible to remove the memory modules 130 for repair or replacement. In order to provide easier access the memory modules 130, the heat sink 302 can be reconfigured by removing the lateral fin assemblies 306, as shown in FIG. 4. In order to remove the lateral fin assemblies 106, in one embodiment, the lateral fin assemblies 106 can be pulled apart along the axis of the spring 314 and then lifted from the core fin assembly 304. With the lateral fin assemblies 306 removed, the memory modules 130 or other components under the lateral fin assembly 306 can be serviced. It should be appreciated that, in the illustrative embodiment, the core heat fin assembly 304 remains mated with the integrated circuit component 124 when the lateral fin assemblies 306 are removed.

After the memory modules 130 or other components are serviced, the lateral fin assemblies 306 can be reattached. In the illustrative embodiment, any previous TIM layer is removed from the metal blocks 112, 305, and a new TIM layer is applied before reattaching the lateral fin assemblies 306.

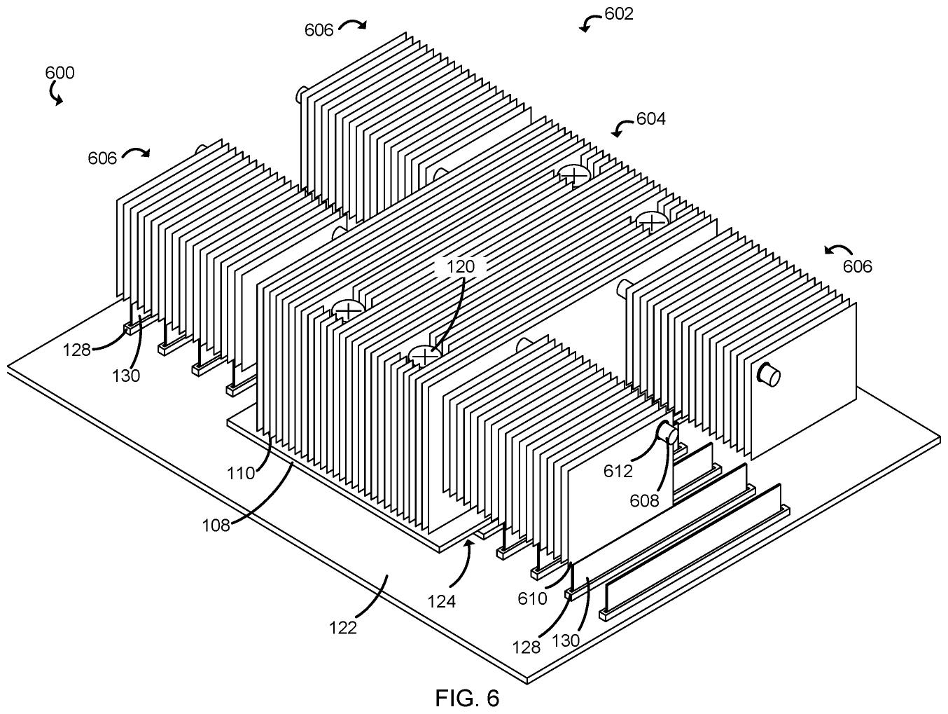

Referring now to FIG. 6, in one embodiment, a system 600 includes a heat sink 602. The heat sink 602 has a core fin assembly 604 and four lateral fin assemblies 606. The lateral fin assemblies 606 are mounted to a heat pipe 608. In the illustrative embodiment, the lateral fin assemblies 606 include a hollow cylinder (not visible in FIG. 6) that slides onto the heat pipe. Fins 610 are connected to a hollow cylinder. One or more O-rings 612 retain the lateral fin assemblies on the heat pipe 608. In the illustrative embodiment, a TIM layer is between the heat pipe 608 and the hollow cylinder on which the fins are mounted, maintaining thermal contact between the heat pipe 608 and the hollow cylinder. The heat pipe 608 is thermally coupled to the base 108, and, therefore, the fins 610 are also thermally coupled to the base. In the illustrative embodiment, the heat pipe 608 is fixed relative to the base 108, and the lateral fin assemblies 606 is rotatable about the axis of the heat pipe 608. In one embodiment, the heat sink 602 can be assembled by applying a TIM to each heat pipe 608 and/or to the hollow cylinder of each lateral fin assembly 606 and then sliding the lateral fin assembly 606 onto the corresponding heat pipe 608. An O-ring 612 or other retaining mechanism may be placed at one or both ends of each lateral fin assembly 606 to retain the lateral fin assembly 606.

The system 600 includes several components similar or identical to those described above in regard to the system 100. For example, the heat sink 602 includes a base 108, fins 110, and one or more fasteners 120, which may be similar to the corresponding component of the heat sink 102. The system 600 includes a system board 122, an integrated circuit component 124, one or more memory module slots 128, one or more memory modules 130, etc. The description of each corresponding component of the system 600 will not be repeated in the interest of clarity.

In use, in the configuration shown in FIG. 6, the lateral fin assemblies 606 are above the memory modules 130, partially or completely block access the memory modules 130 for servicing. It should be appreciated that, in the illustrative embodiment, the system 600 can fit within a 2U form factor in the configuration shown in FIG. 6.

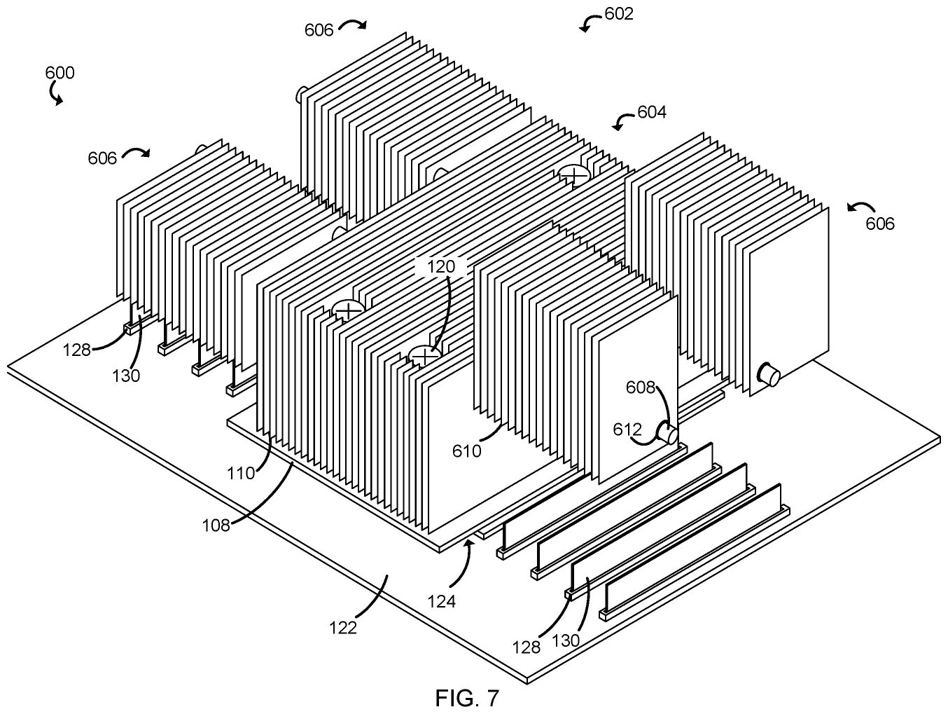

Referring now to FIG. 7, in use, some or all of the lateral fin assemblies 606 can be rotated from the position shown in FIG. 6 to the position shown in FIG. 7. As used herein, the position of an object (such as the lateral fin assemblies 606) refers to both the location and orientation of the object. As such, a change in position can refer to a change in location, a change in orientation, or a change in both location and orientation. In the position shown in FIG. 7, the lateral fin assemblies 606 are rotated up, out of the way of the memory modules 130 or other components under the lateral fin assemblies 606, allowing the memory modules 130 to be serviced. In the illustrative embodiment, the lateral fin assemblies 606 in the configuration shown in FIG. 7 do not fit within a 2U form factor. As such, a sled or blade may be slid forward in a rack for servicing prior to the rotation of the lateral fin assemblies 606. After servicing of the memory modules 130 is complete, the lateral fin assemblies 606 can be rotated back to the configuration shown in FIG. 6, and the sled or blade including the system 600 can be slid back into place for operation. In the illustrative embodiment, the lateral fin assemblies 606 do not need to be removed from the heat pipe 608. As such, a TIM layer does not need to be reapplied before operation of the system 600 is resumed, with little or no decrease in cooling capacity in the lateral fin assemblies 606.

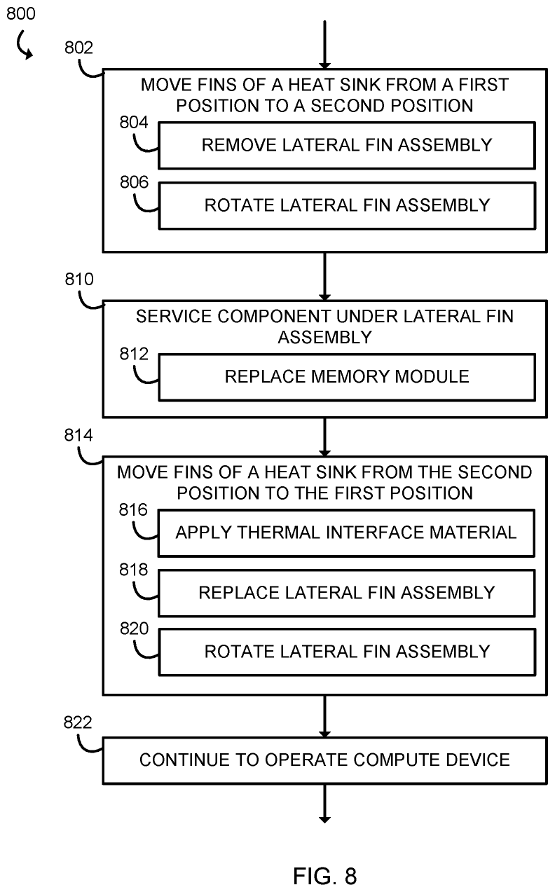

Referring now to FIG. 8, in one embodiment, a method 800 for servicing a compute device (which may include or be included in the system 100, 300, or 600) begins in block 802, in which an administrator moves fins (such as lateral fin assembly 106, 306, 606) of a heat sink (such as heat sink 102, 302, 602) from a first position to a second position. For example, in one embodiment, a lateral fin assembly 106, 306 may be removed from a core fin assembly 104, 304 in block 804. In another embodiment, a lateral fin assembly 606 may be rotated around a heat pipe 608 coupled to a core fin assembly 604. In some embodiments, prior to moving the fins of the heat sink, the compute device may be pulled out from a rack in a sled or blade, allowing the administrator access to the compute device.

In block 810, the administrator services one or more components under a lateral fin assembly, such as lateral fin assembly 106, 306, 606. For example, in the illustrative embodiment, the administrator replaces one or more memory modules 130 in block 812.

In block 814, the administrator moves the fins of the heat sink from the second position back into the first position. In one embodiment, the administrator may apply a thermal interface material (TIM) to one or more surfaces in block 816, and then replace the lateral fin assembly in block 818. In another embodiment, the administrator may rotate a lateral fin assembly in block 820.

In block 822, the administrator continues to operate the compute device. The administrator may return the compute device in a sled or rack into a close position of a rack in order to continue to operate it.

It should be appreciated that embodiments are envisioned beyond those shown in FIGS. 1-7. For example, in one embodiment, a system may include several heat sinks 102, 302, and/or 602, such as in a multi-processor system. The multiple heat sinks may be in a side-to-side configuration or in a shadowed configuration. The lateral fin assemblies 106, 306, 606 are shown to the side of the corresponding core fin assembly 104, 304, 604. Additionally or alternatively, in some embodiments, the lateral fin assemblies 106, 306, 606 may be in front or behind the corresponding core fin assembly 104, 304, 306. A system may include any suitable number of lateral fin assemblies 106, 306, and/or 606 connected to a single core fin assembly 104, 304, and/or 604, such as 1-8 lateral fin assemblies 106, 306, and/or 606.

The technologies described herein can be performed by or implemented in any of a variety of computing systems, including rack-level computing solutions (e.g., blades, trays, sleds), desktop computers, servers, workstations, stationary gaming consoles, set-top boxes, smart televisions, computing systems that are part of a vehicle, smart home appliance, consumer electronics product or equipment, manufacturing equipment, etc. As used herein, the term “computing system” includes computing devices and includes systems comprising multiple discrete physical components. In some embodiments, the computing systems are located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center or a micro data center (e.g., a data center, typically having a smaller footprint than other data center types, located close to the geographic area that it serves).

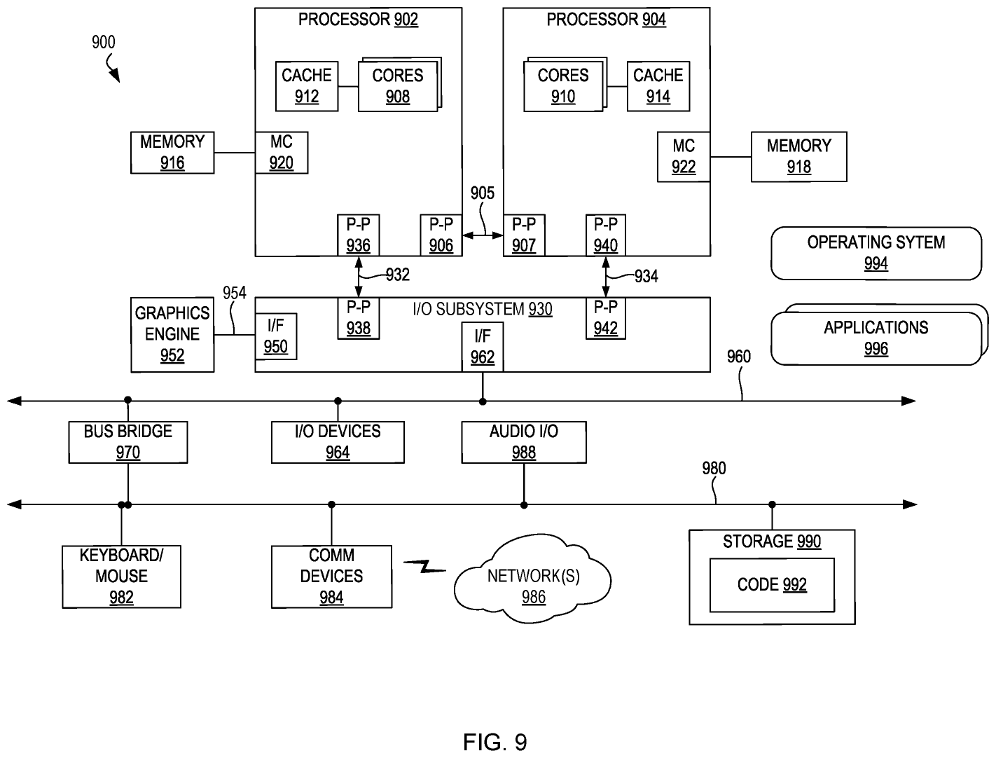

FIG. 9 is a block diagram of an example computing system in which technologies described herein may be implemented. Generally, components shown in FIG. 9 can communicate with other shown components, although not all connections are shown, for ease of illustration. The computing system 900 is a multiprocessor system comprising a first processor unit 902 and a second processor unit 904 comprising point-to-point (P-P) interconnects. A point-to-point (P-P) interface 906 of the processor unit 902 is coupled to a point-to-point interface 907 of the processor unit 904 via a point-to-point interconnection 905. It is to be understood that any or all of the point-to-point interconnects illustrated in FIG. 9 can be alternatively implemented as a multi-drop bus, and that any or all buses illustrated in FIG. 9 could be replaced by point-to-point interconnects.

The processor units 902 and 904 comprise multiple processor cores. Processor unit 902 comprises processor cores 908 and processor unit 904 comprises processor cores 910. Processor units 902 and 904 further comprise cache memories 912 and 914, respectively. The cache memories 912 and 914 can store data (e.g., instructions) utilized by one or more components of the processor units 902 and 904, such as the processor cores 908 and 910. The cache memories 912 and 914 can be part of a memory hierarchy for the computing system 900. For example, the cache memories 912 can locally store data that is also stored in a memory 916 to allow for faster access to the data by the processor unit 902. In some embodiments, the cache memories 912 and 914 can comprise multiple cache levels, such as level 1 (L1), level 2 (L2), level 3 (L3), level 4 (L4), and/or other caches or cache levels, such as a last level cache (LLC). Some of these cache memories (e.g., L2, L3, L4, LLC) can be shared among multiple cores in a processor unit. One or more of the higher levels of cache levels (the smaller and faster caches) in the memory hierarchy can be located on the same integrated circuit die as a processor core and one or more of the lower cache levels (the larger and slower caches) can be located on an integrated circuit dies that are physically separate from the processor core integrated circuit dies.

Although the computing system 900 is shown with two processor units, the computing system 900 can comprise any number of processor units. Further, a processor unit can comprise any number of processor cores. A processor unit can take various forms such as a central processing unit (CPU), a graphics processing unit (GPU), general-purpose GPU (GPGPU), accelerated processing unit (APU), field-programmable gate array (FPGA), neural network processing unit (NPU), data processor unit (DPU), accelerator (e.g., graphics accelerator, digital signal processor (DSP), compression accelerator, artificial intelligence (AI) accelerator), controller, or other types of processing units. As such, the processor unit can be referred to as an XPU (or xPU). Further, a processor unit can comprise one or more of these various types of processing units. In some embodiments, the computing system comprises one processor unit with multiple cores, and in other embodiments, the computing system comprises a single processor unit with a single core. As used herein, the terms “processor unit” and “processing unit” can refer to any processor, processor core, component, module, engine, circuitry, or any other processing element described or referenced herein.

In some embodiments, the computing system 900 can comprise one or more processor units that are heterogeneous or asymmetric to another processor unit in the computing system. There can be a variety of differences between the processing units in a system in terms of a spectrum of metrics of merit including architectural, microarchitectural, thermal, power consumption characteristics, and the like. These differences can effectively manifest themselves as asymmetry and heterogeneity among the processor units in a system.

The processor units 902 and 904 can be located in a single integrated circuit component (such as a multi-chip package (MCP) or multi-chip module (MCM)) or they can be located in separate integrated circuit components. An integrated circuit component comprising one or more processor units can comprise additional components, such as embedded DRAM, stacked high bandwidth memory (HBM), shared cache memories (e.g., L3, L4, LLC), input/output (I/O) controllers, or memory controllers. Any of the additional components can be located on the same integrated circuit die as a processor unit, or on one or more integrated circuit dies separate from the integrated circuit dies comprising the processor units. In some embodiments, these separate integrated circuit dies can be referred to as “chiplets”. In some embodiments where there is heterogeneity or asymmetry among processor units in a computing system, the heterogeneity or asymmetric can be among processor units located in the same integrated circuit component.

Processor units 902 and 904 further comprise memory controller logic (MC) 920 and 922. As shown in FIG. 9, MCs 920 and 922 control memories 916 and 99 coupled to the processor units 902 and 904, respectively. The memories 916 and 918 can comprise various types of volatile memory (e.g., dynamic random-access memory (DRAM), static random-access memory (SRAM)) and/or non-volatile memory (e.g., flash memory, chalcogenide-based phase-change non-volatile memories), and comprise one or more layers of the memory hierarchy of the computing system. While MCs 920 and 922 are illustrated as being integrated into the processor units 902 and 904, in alternative embodiments, the MCs can be external to a processor unit.

Processor units 902 and 904 are coupled to an Input/Output (I/O) subsystem 930 via point-to-point interconnections 932 and 934. The point-to-point interconnection 932 connects a point-to-point interface 936 of the processor unit 902 with a point-to-point interface 938 of the I/O subsystem 930, and the point-to-point interconnection 934 connects a point-to-point interface 940 of the processor unit 904 with a point-to-point interface 942 of the I/O subsystem 930. Input/Output subsystem 930 further includes an interface 950 to couple the I/O subsystem 930 to a graphics engine 952. The I/O subsystem 930 and the graphics engine 952 are coupled via a bus 954.

The Input/Output subsystem 930 is further coupled to a first bus 960 via an interface 962. The first bus 960 can be a Peripheral Component Interconnect Express (PCIe) bus or any other type of bus. Various I/O devices 964 can be coupled to the first bus 960. A bus bridge 970 can couple the first bus 960 to a second bus 980. In some embodiments, the second bus 980 can be a low pin count (LPC) bus. Various devices can be coupled to the second bus 980 including, for example, a keyboard/mouse 982, audio I/O devices 988, and a storage device 990, such as a hard disk drive, solid-state drive, or another storage device for storing computer-executable instructions (code) 992 or data. The code 992 can comprise computer-executable instructions for performing methods described herein. Additional components that can be coupled to the second bus 980 include communication device(s) 984, which can provide for communication between the computing system 900 and one or more wired or wireless networks 986 (e.g. Wi-Fi, cellular, or satellite networks) via one or more wired or wireless communication links (e.g., wire, cable, Ethernet connection, radio-frequency (RF) channel, infrared channel, Wi-Fi channel) using one or more communication standards (e.g., IEEE 802.11 standard and its supplements).

In embodiments where the communication devices 984 support wireless communication, the communication devices 984 can comprise wireless communication components coupled to one or more antennas to support communication between the computing system 900 and external devices. The wireless communication components can support various wireless communication protocols and technologies such as Near Field Communication (NFC), IEEE 1002.11 (Wi-Fi) variants, WiMax, Bluetooth, Zigbee, 4G Long Term Evolution (LTE), Code Division Multiplexing Access (CDMA), Universal Mobile Telecommunication System (UMTS) and Global System for Mobile Telecommunication (GSM), and 5G broadband cellular technologies. In addition, the wireless modems can support communication with one or more cellular networks for data and voice communications within a single cellular network, between cellular networks, or between the computing system and a public switched telephone network (PSTN).

The system 900 can comprise removable memory such as flash memory cards (e.g., SD (Secure Digital) cards), memory sticks, Subscriber Identity Module (SIM) cards). The memory in system 900 (including caches 912 and 914, memories 916 and 918, and storage device 990) can store data and/or computer-executable instructions for executing an operating system 994 and application programs 996. Example data includes web pages, text messages, images, sound files, and video data to be sent to and/or received from one or more network servers or other devices by the system 900 via the one or more wired or wireless networks 986, or for use by the system 900. The system 900 can also have access to external memory or storage (not shown) such as external hard drives or cloud-based storage.

The operating system 994 can control the allocation and usage of the components illustrated in FIG. 9 and support the one or more application programs 996. The application programs 996 can include common computing system applications (e.g., email applications, calendars, contact managers, web browsers, messaging applications) as well as other computing applications.

The computing system 900 can support various additional input devices, such as a touchscreen, microphone, monoscopic camera, stereoscopic camera, trackball, touchpad, trackpad, proximity sensor, light sensor, electrocardiogram (ECG) sensor, PPG (photoplethysmogram) sensor, galvanic skin response sensor, and one or more output devices, such as one or more speakers or displays. Other possible input and output devices include piezoelectric and other haptic I/O devices. Any of the input or output devices can be internal to, external to, or removably attachable with the system 900. External input and output devices can communicate with the system 900 via wired or wireless connections.

In addition, the computing system 900 can provide one or more natural user interfaces (NUIs). For example, the operating system 994 or applications 996 can comprise speech recognition logic as part of a voice user interface that allows a user to operate the system 900 via voice commands. Further, the computing system 900 can comprise input devices and logic that allows a user to interact with computing the system 900 via body, hand or face gestures.

The system 900 can further include at least one input/output port comprising physical connectors (e.g., USB, IEEE 1394 (FireWire), Ethernet, RS-232), a power supply (e.g., battery), a global satellite navigation system (GNSS) receiver (e.g., GPS receiver); a gyroscope; an accelerometer; and/or a compass. A GNSS receiver can be coupled to a GNSS antenna. The computing system 900 can further comprise one or more additional antennas coupled to one or more additional receivers, transmitters, and/or transceivers to enable additional functions.

It is to be understood that FIG. 9 illustrates only one example computing system architecture. Computing systems based on alternative architectures can be used to implement technologies described herein. For example, instead of the processors 902 and 904 and the graphics engine 952 being located on discrete integrated circuits, a computing system can comprise an SoC (system-on-a-chip) integrated circuit incorporating multiple processors, a graphics engine, and additional components. Further, a computing system can connect its constituent component via bus or point-to-point configurations different from that shown in FIG. 9. Moreover, the illustrated components in FIG. 9 are not required or all-inclusive, as shown components can be removed and other components added in alternative embodiments.

As used in this application and in the claims, a list of items joined by the term “and/or” can mean any combination of the listed items. For example, the phrase “A, B and/or C” can mean A; B; C; A and B; A and C; B and C; or A, B and C. As used in this application and in the claims, a list of items joined by the term “at least one of” can mean any combination of the listed terms. For example, the phrase “at least one of A, B or C” can mean A; B; C; A and B; A and C; B and C; or A, B and C. Moreover, as used in this application and in the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

### EXAMPLES

Illustrative examples of the technologies disclosed herein are provided below. An embodiment of the technologies may include any one or more, and any combination of, the examples described below.

Example 1 includes a heat sink comprising a base to thermally couple to an integrated circuit component; a core fin assembly comprising a first plurality of fins, wherein individual fins of the first plurality of fins are thermally coupled to the base and fixed in position relative to the base; and a lateral fin assembly comprising a second plurality of fins, wherein individual fins of the second plurality of fins are thermally coupled to the base, wherein the lateral fin assembly is movable relative to the base.

Example 2 includes the subject matter of Example 1, and wherein the second plurality of fins are mechanically mated to a heat pipe thermally coupled to the base, wherein the second plurality of fins are rotatable relative to the heat pipe.

Example 3 includes the subject matter of any of Examples 1 and 2, and further including one or more O-rings, wherein the one or more O-rings retain the second plurality of fins on the heat pipe.

Example 4 includes the subject matter of any of Examples 1-3, and wherein the second plurality of fins are able to rotate at least 90° relative to the heat pipe.

Example 5 includes the subject matter of any of Examples 1-4, and wherein the second plurality of fins are able to rotate at least 180° relative to the heat pipe.

Example 6 includes the subject matter of any of Examples 1-5, and further including a thermal interface material between the second plurality of fins and the heat pipe.

Example 7 includes the subject matter of any of Examples 1-6, and further including a first thermally conductive block thermally coupled to the base, wherein the lateral fin assembly comprises a second thermally conductive block, wherein the second plurality of fins are mechanically mated to the second thermally conductive block, wherein the second thermally conductive block is removably fastened to the first thermally conductive block.

Example 8 includes the subject matter of any of Examples 1-7, and wherein the second thermally conductive block has a flat surface that mates with a flat surface of the first thermally conductive block, wherein the second thermally conductive block has an edge, wherein the edge has a wedged shape, wherein the wedged-shaped edge of the second thermally conductive block mates with a protrusion extending from the flat surface of the first thermally conductive block, further comprising a spring to apply a force to the second thermally conductive block in a direction in a plane defined by the flat surface of the second thermally conductive block, wherein the spring applies a force through the second thermally conductive block to the wedged-shaped edge toward the protrusion extending from the flat surface of the first thermally conductive block, wherein the protrusion extending from the flat surface of the first thermally conductive block applies a force normal to a surface of the wedged-shaped edge, wherein the force normal to the surface of the wedged-shaped edge is at least partially a force perpendicular to the flat surface of the first thermally conductive block.

Example 9 includes the subject matter of any of Examples 1-8, and further including a second lateral fin assembly comprising a third plurality of fins, wherein individual fins of the third plurality of fins are thermally coupled to the base, wherein the third plurality of fins is movable relative to the base; and a third thermally conductive block thermally coupled to the base, wherein the second lateral fin assembly comprises a fourth thermally conductive block, wherein the third plurality of fins are mechanically mated to the fourth thermally conductive block, wherein the fourth thermally conductive block is removably fastened to the third thermally conductive block, further comprising a spring mechanically coupled to the lateral fin assembly and the second lateral fin assembly, wherein the spring applies a force to the lateral fin assembly towards the second lateral fin assembly and applies a force to the second lateral fin assembly towards the lateral fin assembly.

Example 10 includes the subject matter of any of Examples 1-9, and further including a thermal interface material between the first thermally conductive block and the second thermally conductive block.

Example 11 includes a system comprising the heat sink of claim 1, the system further comprising the integrated circuit component thermally coupled to the heat sink; a mainboard, the integrated circuit component mated with the mainboard; and one or more memory modules mechanically coupled to the mainboard and communicatively coupled to the integrated circuit component, wherein the lateral fin assembly is positioned above one of the one or more memory modules.

Example 12 includes a method comprising moving a first plurality of fins of a heat sink from a first position to a second position relative to a base of the heat sink, wherein the base is thermally coupled to an integrated circuit component, wherein the integrated circuit component is mated with a mainboard, wherein the heat sink comprises a second plurality of fins, wherein individual fins of the first plurality of fins are thermally coupled to the base, wherein individual fins of the second plurality of fins are thermally coupled to the base, wherein the second plurality of fins are fixed in position relative to the base, removing one or more memory modules from one or more memory module slots of the mainboard while the first plurality of fins is in the second position; adding one or more new memory modules to the one or more memory module slots while the first plurality of fins is in the second position; and moving the first plurality of fins of the heat sink from the second position to the first position after adding the one or more new memory modules, wherein the first plurality of fins prevents removal of the one or more memory modules from the one or more memory module slots in the first position, wherein the first plurality of fins does not prevent removal of the one or more memory modules from the one or more memory module slots in the second position.

Example 13 includes the subject matter of Example 12, and wherein the first plurality of fins are mechanically mated to a heat pipe thermally coupled to the base, wherein moving the first plurality of fins from the first position to the second position comprises rotating the first plurality of fins relative to the heat pipe.

Example 14 includes the subject matter of any of Examples 12 and 13, and wherein one or more O-rings retain the first plurality of fins on the heat pipe.

Example 15 includes the subject matter of any of Examples 12-14, and wherein the first plurality of fins are able to rotate at least 90° relative to the heat pipe.

Example 16 includes the subject matter of any of Examples 12-15, and wherein the first plurality of fins are able to rotate at least 180° relative to the heat pipe.

Example 17 includes the subject matter of any of Examples 12-16, and wherein a thermal interface material is between the first plurality of fins and the heat pipe.

Example 18 includes the subject matter of any of Examples 12-17, and wherein a first thermally conductive block is thermally coupled to the base, wherein the first plurality of fins are mechanically mated to a second thermally conductive block, wherein the second thermally conductive block is removably fastened to the first thermally conductive block, wherein moving the first plurality of fins from the first position to the second position comprises removing the second thermally conductive block from the first thermally conductive block.

Example 19 includes the subject matter of any of Examples 12-18, and wherein the second thermally conductive block has a flat surface that mates with a flat surface of the first thermally conductive block, wherein the second thermally conductive block has an edge, wherein the edge has a wedged shape, wherein the wedged-shaped edge of the second thermally conductive block mates with a protrusion extending from the flat surface of the first thermally conductive block, wherein moving the first plurality of fins of the heat sink from the second position to the first position comprises fastening a spring to the second thermally conductive block to apply a force to the second thermally conductive block in a direction in a plane defined by the flat surface of the second thermally conductive block, wherein the spring applies a force through the second thermally conductive block to the wedged-shaped edge toward the protrusion extending from the flat surface of the first thermally conductive block, wherein the protrusion extending from the flat surface of the first thermally conductive block applies a force normal to a surface of the wedged-shaped edge, wherein the force normal to the surface of the wedged-shaped edge is at least partially a force perpendicular to the flat surface of the first thermally conductive block.

Example 20 includes the subject matter of any of Examples 12-19, and wherein the heat sink comprises a third plurality of fins, wherein individual fins of the third plurality of fins are thermally coupled to the base, wherein the third plurality of fins is movable relative to the base, wherein the heat sink comprises a third thermally conductive block thermally coupled to the base; wherein the heat sink comprises a fourth thermally conductive block, wherein the third plurality of fins are mechanically mated to the fourth thermally conductive block, wherein the fourth thermally conductive block is removably fastened to the third thermally conductive block, wherein the heat sink comprises a spring mechanically coupled to the second thermally conductive block and the fourth thermally conductive block, wherein the spring applies a force to the second thermally conductive block towards the fourth thermally conductive block and applies a force to the fourth thermally conductive block towards the second thermally conductive block, wherein moving the first plurality of fins of the heat sink from the first position to the second position comprises pulling the second thermally conductive block away from the fourth thermally conductive block.

Example 21 includes the subject matter of any of Examples 12-20, and wherein the heat sink comprises a thermal interface material between the first thermally conductive block and the second thermally conductive block.

Example 22 includes a heat sink comprising a first means for cooling an integrated circuit component, the first means thermally coupled to the integrated circuit component mated with the integrated circuit component; and a second means for cooling the integrated circuit component, the second means thermally and mechanically coupled to the first means, wherein the second means is movable relative to the first means.

Example 23 includes the subject matter of Example 22, and wherein the second means is rotatable relative to the first means.

Example 24 includes the subject matter of any of Examples 22 and 23, and wherein the second means is removable from the first means.

1. A heat sink comprising:
a base to thermally couple to an integrated circuit component;
a core fin assembly comprising a first plurality of fins, wherein individual fins of the first plurality of fins are thermally coupled to the base and fixed in position relative to the base; and
a lateral fin assembly comprising a second plurality of fins, wherein individual fins of the second plurality of fins are thermally coupled to the base, wherein the lateral fin assembly is movable relative to the base.

2. The heat sink of claim 1, wherein the second plurality of fins are mechanically mated to a heat pipe thermally coupled to the base, wherein the second plurality of fins are rotatable relative to the heat pipe.

3. The heat sink of claim 2, further comprising one or more O-rings, wherein the one or more O-rings retain the second plurality of fins on the heat pipe.

4. The heat sink of claim 2, wherein the second plurality of fins are able to rotate at least 90° relative to the heat pipe.

5. The heat sink of claim 2, wherein the second plurality of fins are able to rotate at least 180° relative to the heat pipe.

6. The heat sink of claim 2, further comprising a thermal interface material between the second plurality of fins and the heat pipe.

7. The heat sink of claim 1, further comprising a first thermally conductive block thermally coupled to the base,
wherein the lateral fin assembly comprises a second thermally conductive block, wherein the second plurality of fins are mechanically mated to the second thermally conductive block,
wherein the second thermally conductive block is removably fastened to the first thermally conductive block.

8. The heat sink of claim 7, wherein the second thermally conductive block has a flat surface that mates with a flat surface of the first thermally conductive block,
wherein the second thermally conductive block has an edge, wherein the edge has a wedged shape,
wherein the wedged-shaped edge of the second thermally conductive block mates with a protrusion extending from the flat surface of the first thermally conductive block,
further comprising a spring to apply a force to the second thermally conductive block in a direction in a plane defined by the flat surface of the second thermally conductive block,
wherein the spring applies a force through the second thermally conductive block to the wedge-shaped edge toward the protrusion extending from the flat surface of the first thermally conductive block,
wherein the protrusion extending from the flat surface of the first thermally conductive block applies a force normal to a surface of the wedge-shaped edge, wherein the force normal to the surface of the wedge-shaped edge is at least partially a force perpendicular to the flat surface of the first thermally conductive block.

9. The heat sink of claim 7, further comprising:
a second lateral fin assembly comprising a third plurality of fins, wherein individual fins of the third plurality of fins are thermally coupled to the base, wherein the third plurality of fins is movable relative to the base; and
a third thermally conductive block thermally coupled to the base;
wherein the second lateral fin assembly comprises a fourth thermally conductive block, wherein the third plurality of fins are mechanically mated to the fourth thermally conductive block,
wherein the fourth thermally conductive block is removably fastened to the third thermally conductive block,
further comprising a spring mechanically coupled to the lateral fin assembly and the second lateral fin assembly, wherein the spring applies a force to the lateral fin assembly towards the second lateral fin assembly and applies a force to the second lateral fin assembly towards the first lateral fin assembly.

10. The heat sink of claim 7, further comprising a thermal interface material between the first thermally conductive block and the second thermally conductive block.

11. A system comprising the heat sink of claim 1, the system further comprising:
the integrated circuit component thermally coupled to the heat sink;
a mainboard, the integrated circuit component mated with the mainboard; and
one or more memory modules mechanically coupled to the mainboard and communicatively coupled to the integrated circuit component,
wherein the lateral fin assembly is positioned above one of the one or more memory modules.

12. A method comprising:
moving a first plurality of fins of a heat sink from a first position to a second position relative to a base of the heat sink,
wherein the base is thermally coupled to an integrated circuit component, wherein the integrated circuit component is mated with a mainboard,
wherein the heat sink comprises a second plurality of fins,
wherein individual fins of the first plurality of fins are thermally coupled to the base,
wherein individual fins of the second plurality of fins are thermally coupled to the base,
wherein the second plurality of fins are fixed in position relative to the base,
removing one or more memory modules from the one or more memory module slots of the mainboard while the plurality of fins are in the second position;
adding one or more new memory modules to the one or more memory module slots while the first plurality of fins are in the second position; and
moving the first plurality of fins of the heat sink from the second position to the first position after adding the one or more new memory modules,
wherein the first plurality of fins prevents removal of the one or more memory modules from the one or more memory module slots in the first position,
wherein the first plurality of fins does not prevent removal of the one or more memory modules from the one or more memory module slots in the second position.

13. The method of claim 12, wherein the first plurality of fins are mechanically mated to a heat pipe thermally coupled to the base, wherein moving the first plurality of fins from the first position to the second position comprises rotating the first plurality of fins relative to the heat pipe.

14. The method of claim 13, wherein one or more O-rings retain the first plurality of fins on the heat pipe.

15. The method of claim 13, wherein the first plurality of fins are able to rotate at least 90° relative to the heat pipe.

16. The method of claim 13, wherein the first plurality of fins are able to rotate at least 180° relative to the heat pipe.

17. The method of claim 13, wherein a thermal interface material is between the first plurality of fins and the heat pipe.

18. The method of claim 12, wherein a first thermally conductive block is thermally coupled to the base,
wherein the first plurality of fins are mechanically mated to a second thermally conductive block,
wherein the second thermally conductive block is removably fastened to the first thermally conductive block,
wherein moving the first plurality of fins from the first position to the second position comprises removing the second thermally conductive block from the first thermally conductive block.

19. The method of claim 18, wherein the second thermally conductive block has a flat surface that mates with a flat surface of the first thermally conductive block,
wherein the second thermally conductive block has an edge, wherein the edge has a wedged shape,
wherein the wedged-shaped edge of the second thermally conductive block mates with a protrusion extending from the flat surface of the first thermally conductive block,
wherein moving the first plurality of fins of the heat sink from the second position to the first position comprises fastening a spring to the second thermally conductive block to apply a force to the second thermally conductive block in a direction in a plane defined by the flat surface of the second thermally conductive block,
wherein the spring applies a force through the second thermally conductive block to the wedge-shaped edge toward the protrusion extending from the flat surface of the first thermally conductive block,
wherein the protrusion extending from the flat surface of the first thermally conductive block applies a force normal to a surface of the wedge-shaped edge, wherein the force normal to the surface of the wedge-shaped edge is at least partially a force perpendicular to the flat surface of the first thermally conductive block.

20. The method of claim 18, wherein the heat sink comprises a third plurality of fins, wherein individual fins of the third plurality of fins are thermally coupled to the base, wherein the third plurality of fins is movable relative to the base,
wherein the heat sink comprises a third thermally conductive block thermally coupled to the base;
wherein the heat sink comprises a fourth thermally conductive block, wherein the third plurality of fins are mechanically mated to the fourth thermally conductive block,
wherein the fourth thermally conductive block is removably fastened to the third thermally conductive block,
wherein the heat sink comprises a spring mechanically coupled to the second thermally conductive block and the fourth thermally conductive block, wherein the spring applies a force to the second thermally conductive block towards the fourth thermally conductive block and applies a force to the fourth thermally conductive block towards the second thermally conductive block,
wherein moving the first plurality of fins of the heat sink from the first position to the second position comprises pulling the second thermally conductive block away from the fourth thermally conductive block.

21. The method of claim 18, wherein the heat sink comprises a thermal interface material between the first thermally conductive block and the second thermally conductive block.

22. A heat sink comprising:
a first means for cooling an integrated circuit component, the first means thermally coupled to the integrated circuit component mated with the integrated circuit component; and
a second means for cooling the integrated circuit component, the second means thermally and mechanically coupled to the first means,
wherein the second means is movable relative to the first means.

23. The heat sink of claim 22, wherein the second means is rotatable relative to the first means.

24. The heat sink of claim 22, wherein the second means is removable from the first means.
